(19) United States
(12) Patent Application Publication
(10) Pub. No.: US 2006/0186519 A1
(43) Pub. Date: Aug. 24, 2006

(54) Semiconductor device and unit equipped with the same

(76) Inventors: Taizo Inoue, Gunma (JP); Kenzo Kitazaki, Gunma (JP); Hisashi Shigetani, Gunma (JP); Eiji Mugiya, Gunma (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/334,106

(22) Filed: Jan. 17, 2006

(30) Foreign Application Priority Data
Jan. 20, 2005 (JP) 2005-012839

(51) Int. Cl. H01L 23/02

(52) U.S. Cl. 257/678

(57) ABSTRACT

A semiconductor device comprises columnar electrodes including columnar portions and ball-shaped low-melting point layers joined to the top surfaces of columnar portions. The amount of plating of the low-melting point layer and the cross-sectional area of the columnar portion are adjusted in such a way that the relationship represented by A≦1.3×B^{1.5} is satisfied, where the volume of each of the low-melting point layers is represented by A and the area of the top surface of each of the columnar portions is represented by B. Consequently, the low-melting point layer is prevented from trickling on a side surface of the columnar portion during formation of the ball by reflow of the low-melting point layer.

### BACKGROUND OF THE INVENTION

1. Field of the Invention

The present invention relates to a semiconductor device and a unit equipped with the same, and in particular, it relates to a semiconductor device useful for pitch reduction, as well as a unit equipped with the same.

2. Description of the Related Technology

The structure of a semiconductor device, just as represented by a chip size package (CSP), has been configured to form the shape closer to a bare chip, as the miniaturization of the integrated circuit has been required. Consequently, a technique of joining this semiconductor device to a wiring substrate by flip chip mounting method has gained the attention.

The joining of the semiconductor device to the wiring substrate by the above-described flip chip mounting method is conducted by interposing bumps disposed on a main surface side of the semiconductor substrate comprising the semiconductor device. In order to arrange the bumps with small pitches therebetween, the volume of each of the bumps must be reduced to avoid adjacent bumps from contacting each other.

However, when the volume of each of the bumps is reduced, a gap between the semiconductor substrate and the wiring substrate is decreased. Therefore, underfilling, by which a resin is filled in the gap for stable joining and to improve or ensure the connection reliability, becomes difficult.

Consequently, in order to ensure the above-described gap, a joint bump using a post-shaped metal column has been proposed. Semiconductor devices using this type of post-shaped joint bump and methods of mounting them have been disclosed, for example, in Japanese Unexamined Patent Application Publications No. 5-136201 and No. 2002-313993, and U.S. Pat. No. 6,592,019.

A technique of forming a joint bump having a metal column formed by a wire bonding method is disclosed in the paragraph 0020 and FIG. 1 of the Japanese Unexamined Patent Application Publication No. 5-136201.

A technique of forming a joint bump in which a metal column is formed by a plating method and a solder ball is disposed on the top surface of the metal column is disclosed in the paragraphs 0002 to 0007 and FIGS. 18 to 24 of the Japanese Unexamined Patent Application Publication No. 2002-313993.

A technique in which a metal column and a solder layer disposed thereon are formed by a plating method, and the solder layer is joined to a wiring substrate, and a technique in which the solder layer is temporarily formed into a ball by reflow and is joined to a wiring substrate are disclosed in the column 7 lines 16 to 54 and FIGS. 1 to 3 of the U.S. Pat. No. 6,592,019.

However, in the technique disclosed in the Japanese Unexamined Patent Application Publication No. 5-136201, a wire bump should be formed on a terminal basis. Therefore, application to a semiconductor device having a lot of input and output terminals becomes difficult. In addition, it is difficult to make the heights of individual bumps uniform. Consequently, the application to a recent high-pin-count, narrow-pitch type semiconductor device is considered to be difficult.

In the technique disclosed in the Japanese Unexamined Patent Application Publication No. 2002-313993, as shown in the paragraph 0007 and FIG. 22 thereof, a process to cover the top surfaces of the metal columns is necessary. Therefore, the metal columns must be polished to be in the state shown in FIG. 23 before the solder balls are formed. In addition, there is a problem that a gap for underfilling cannot be ensured since the semiconductor device is constructed while the metal columns are embedded in the resin.

On the other hand, in the technique disclosed in the U.S. Pat. No. 6,592,019, metal columns and solder layers are formed by plating, and mounting them onto a wiring substrate is conducted while the metal columns are exposed. Therefore, this technique is considered to be excellent from the viewpoint of making the heights of individual bumps uniform and ensuring an underfill gap.

However, as is clear from the column 7 lines 47 to 53 in the U.S. Pat. No. 6,592,019, various problems which occur where the solder ball is formed temporarily by reflow of the solder layer disposed on the top surface of the metal layer are not described. Therefore, further study is required in order to precisely form a solder ball on the metal column.

### SUMMARY OF THE INVENTION

Accordingly, it is an object of the present invention to provide a semiconductor device useful for forming a joint bump with a solder ball on the top surface of a columnar portion, as well as a unit equipped with the same.

In order to achieve the above-described object, a semiconductor device according to a first aspect of the present invention is characterized by comprising a plurality of columnar electrodes disposed on a semiconductor substrate, the above-described columnar electrode including a columnar portion made of an electrically conductive material and a metal ball portion made of an electrically conductive material having a melting point lower than that of the above-described columnar portion and joined to the top surface of the above-described columnar portion, wherein the above-described columnar electrode satisfies the relationship represented by A−E≦1.3×B^{1.5}, where the volume of the above-described metal ball portion is represented by A, the area of the top surface of the above-described columnar portion is represented by B, and the volume of an projecting portion disposed on the top surface of the above-described columnar portion is represented by E.

As described above, the volume of the metal ball portion is controlled to be equal to or smaller than a predetermined volume determined by the area of the top surface of the columnar portion and the projecting portion disposed on the top surface. Consequently, the tension generated at the surface in contact with the columnar portion becomes larger than the gravity applied to the metal ball portion and, thereby, when the metal ball portion is formed by reflow of a low-melting point material, the low-melting point material is prevented from trickling on a side surface of the columnar portion.

Here, the projecting portion disposed on the top surface of the columnar portion refers to an projecting portion protruded from a horizontal line when the horizontal line intersecting the side surface of the columnar portion at a right angle is drawn at the top end of the columnar portion. Such a projecting portion may be formed naturally in the plating step or be formed intentionally. The low-melting point material can be prevented from trickling on a side surface of the columnar portion by taking the volume of this projecting portion into consideration.

When these structures are adopted, the surface area of a portion in contact with the low-melting point layer is taken as the above-described area B of the top surface of the columnar portion. Therefore, when these structures are adopted, the volume of the low-melting point layer can be increased since a wide contact area between the low-melting point layer and the columnar portion can be ensured.

As a result, the heights of individual columnar electrodes can be made uniform. Consequently, the joining precision of each electrode relative to the wiring substrate is improved and a structure in which the electrode pitch is minimized while the underfill gap is ensured can be realized.

Furthermore, according to the present technique, the metal ball portion joined to the top surface of the columnar portion can be formed without conducting additional treatment of the side surface of the columnar portion. Therefore, a semiconductor device provided with columnar electrodes having a simple structure and high reliability is produced. However, the present invention does not exclude the treatment of the side surface of the columnar portion. The treatment of the side surface of the columnar portion may be conducted to more reliably prevent the low-melting point material from trickling on the side surface of the columnar portion.

Here, it is desirable that the columnar portion is formed from a material having a low electrical resistance and a high melting point such as copper. It is desirable that the metal ball portion is formed from a material having a low melting point and high conformability to a material constituting the columnar portion such as solder. The columnar portion may be formed from an electrically conductive material, for example, nickel, aluminum, or titanium.

In the semiconductor device according to the first aspect of the present invention, preferably, each of the above-described columnar electrodes satisfies the relationship represented by D<C, where one-half of the pitch between the individual above-described columnar electrodes is represented by C and the height of the above-described metal ball portion is represented by D.

Contact between adjacent columnar electrodes can be avoided during the reflow conducted when the present semiconductor device is mounted on the wiring substrate by further controlling the relationship between the pitch of the columnar electrodes and the height of the metal ball portion, as described above.

A unit equipped with a semiconductor device according to a second aspect of the present invention is characterized in that the semiconductor device includes a plurality of columnar electrodes disposed on a semiconductor substrate and the semiconductor device is mounted on a wiring substrate with the individual columnar electrodes therebetween, the above-described columnar electrode including a columnar portion made of an electrically conductive material and a low-melting point metal layer made of an electrically conductive material having a melting point lower than that of the above-described columnar portion and joined to the top surface of the above-described columnar portion, wherein the above-described columnar electrode satisfies the relationship represented by A−E≦1.3×B^{1.5}, where the volume of the above-described low-melting point metal layer is represented by A, the area of the top surface of the above-described columnar portion is represented by B, and the volume of an projecting portion disposed on the top surface of the above-described columnar portion is represented by E.

As described above, the volume of the metal ball portion is controlled to be smaller than or equal to a predetermined volume determined by the area of the top surface of the columnar portion and the projecting portion disposed on the top surface. Consequently, the semiconductor device can be mounted on the wiring substrate while the low-melting point metal layer is prevented from trickling on a side surface of the columnar portion and, thereby, the heights of individual columnar electrodes can be made uniform. As a result, the joining precision of each electrode relative to the wiring substrate is improved and a structure in which the electrode pitch is minimized while the underfill gap is ensured can be realized.

In the unit equipped with a semiconductor device according to the second aspect of the present invention, preferably, an underfill filled in between the above-described semiconductor device and the above-described wiring substrate while being in direct contact with side surfaces of the above-described columnar portions is provided.

Semiconductor devices can be mounted at narrow pitches while the underfill gap is ensured suitably by adopting such a configuration.

A semiconductor device according to a third aspect of the present invention is characterized by including a plurality of columnar electrodes disposed on a semiconductor substrate, the above-described columnar electrode including a first columnar portion and a second columnar portion both made of an electrically conductive material and a metal ball portion made of an electrically conductive material having a melting point lower than that of the above-described columnar portions and joined to the top surface of the above-described second columnar portion, wherein the above-described second columnar portion includes a section having a diameter smaller than the diameter of the first columnar portion and is interposed between the above-described metal ball portion and the above-described first columnar portion.

As described above, a columnar portion having a small diameter is disposed on a columnar portion having a large diameter and the metal ball portion is disposed on the columnar portion having a small diameter. Consequently, when the metal ball portion is formed by reflow of a low-melting point material, the low-melting point material is prevented from trickling on at least a side surface of the columnar portion having a large diameter.

As a result, even when the low-melting point material trickles on the side surface of the columnar portion having the small diameter, the trickling is stopped on the top surface of the columnar portion having the large diameter. Consequently, the heights of individual columnar electrodes can be made uniform, the joining precision of each electrode relative to the wiring substrate is improved, and a structure in which the electrode pitch is minimized while the underfill gap is ensured can be realized.

Furthermore, according to the present technique, the metal ball portion joined to only the top surface of the columnar portion can also be formed without conducting additional treatment of the side surface of the columnar portion. Therefore, a semiconductor device provided with columnar electrodes having a simple structure and high reliability is produced. However, the present invention does not exclude the treatment of the side surface of the columnar portion. The treatment of the side surface of the columnar portion may be conducted to further prevent the low-melting point material from trickling on the side surface of the columnar portion. In order to prevent trickling more reliably, it is effective to conduct a treatment to prevent trickling on the side surface.

The aspect ratio of an opening disposed in a resist when forming the columnar portion through plating can reduced by forming the columnar portion in two stages, the first and the second stages, as described above. Consequently, electrodes arranged at narrower pitches can be formed.

As described above, according to the present invention, columnar electrodes including ball portions joined to only the top surfaces of columnar portions can be formed.

### BRIEF DESCRIPTION OF THE DRAWINGS

FIG. 1 is a sectional view showing a mounting structure of a semiconductor device according to a first embodiment of the present invention.

FIGS. 2A to 2C are sectional views showing a first production step of the semiconductor device according to the first embodiment.

FIGS. 3A and 3B are sectional views showing a second production step of the semiconductor device according to the first embodiment.

FIGS. 4A and 4B are sectional views showing a third production step of the semiconductor device according to the first embodiment.

FIG. 5 is a sectional view showing a first mounting step of the semiconductor device according to the first embodiment.

FIG. 6 is a sectional view showing a second mounting step of the semiconductor device according to the first embodiment.

FIG. 7 is a sectional view showing another mounting structure of the semiconductor device according to the first embodiment.

FIGS. 8A and 8B are sectional views showing states of columnar electrodes exhibiting low connection reliability.

FIG. 9 is a sectional view showing the relationship between the volume of the low-melting point layer and the area of the top surface of the columnar portion shown in FIG. 4A.

FIG. 10 is a side view showing a reflow step of a wafer provided with columnar electrodes.

FIG. 11 is a sectional view showing an electrode structure of a semiconductor device formed by the step shown in FIG. 10.

FIG. 12 is a table showing the results of verification of the relationship between the volume A of the low-melting point layer and the area B of the top surface of the columnar portion.

FIGS. 13A to 13E are sectional views showing examples of suitable structures of the columnar electrode.

FIG. 14 is a sectional view showing a mounting structure of a semiconductor device according to a second embodiment of the present invention.

FIGS. 15A to 15C are sectional views showing a first production step of the semiconductor device according to the second embodiment.

FIGS. 16A to 16C are sectional views showing a second production step of the semiconductor device according to the second embodiment.

FIGS. 17A and 17B are sectional views showing a third production step of the semiconductor device according to the second embodiment.

FIGS. 18A and 18B are sectional views showing a fourth production step of the semiconductor device according to the second embodiment.

FIG. 19 is a sectional view showing a first mounting step of the semiconductor device according to the second embodiment.

FIG. 20 is a sectional view showing a second mounting step of the semiconductor device according to the second embodiment.

FIG. 21 is a sectional view showing another mounting structure of the semiconductor device according to the second embodiment.

FIGS. 22A and 22B are sectional views showing states of columnar electrodes exhibiting low connection reliability.

FIG. 23 is a sectional view showing an embodiment in the case where a trapezoidal columnar portions are used.

FIG. 24 is a sectional view showing an example of mounting on a semiconductor substrate by using via holes.

FIG. 25 is a sectional view showing an example of joining to an electrode pattern disposed on a semiconductor substrate.

### DESCRIPTION OF CERTAIN EMBODIMENTS

Certain embodiments of the present invention will be described below in detail with reference to the attached drawings. The present invention is not limited to the embodiments described below, and appropriate modifications can be made.

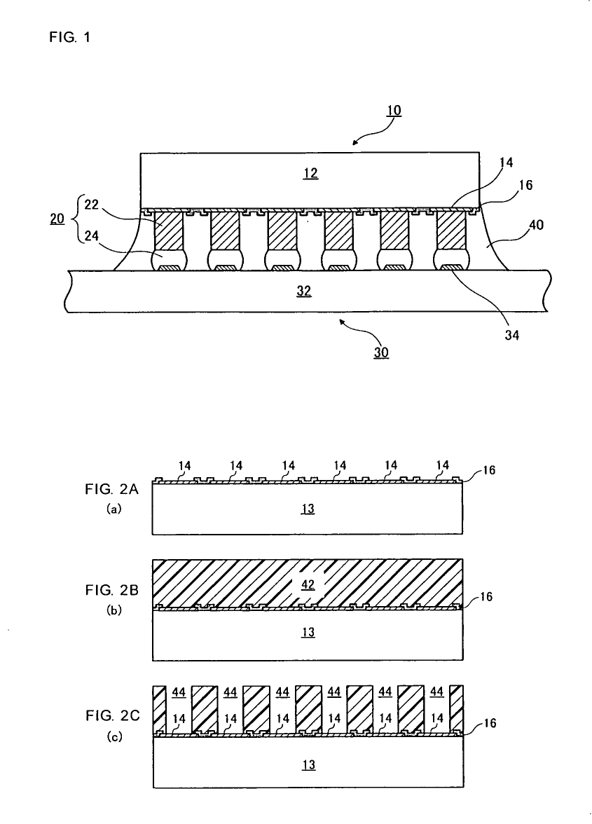

FIG. 1 is a sectional view showing a mounting structure of a semiconductor device according to a first embodiment of the present invention. As shown in FIG. 1, a semiconductor device 10 is mounted on a wiring substrate 30 with columnar electrodes 20 therebetween in the present mounting structure.

The semiconductor device 10 is composed of a semiconductor substrate 12 made of silicon, a plurality of aluminum electrode pads 14 disposed on the main surface side of the semiconductor substrate 12, and a passivation film 16 disposed in such a way that each of the electrode pads is partially exposed.

Each columnar electrode 20 is composed of a columnar portion 22 made of copper and disposed on the exposed portion of each of the above-described electrode pads 14 and a low-melting point layer 24 made of solder and disposed on the top surface of the columnar portion 22. It is desirable that the columnar portion is disposed having a height of 15 μm or more.

The wiring substrate 30 is composed of a multilayer substrate 32 including various pattern layers and a wiring pattern 34 disposed on a surface of the multilayer substrate 32.

Electrical connection between the semiconductor device 10 and the wiring substrate 30 is conducted by melting the low-melting point layers 24 located at front end portions of the columnar electrodes 20 on the wiring pattern 34, and an underfill 40 is applied in between the semiconductor device 10 and the wiring substrate 30, so that the joining state through each of the columnar electrodes 20 is protected.

FIGS. 2A to 2C are sectional views showing a first production step of the semiconductor device according to the first embodiment. In the production of the semiconductor device according to the present embodiment, as shown in FIG. 2A, a plurality of electrode pads 14 are formed on the main surface side of a wafer 13 provided with a plurality of integrated circuits, and a passivation film 16 is formed in such a way that a center portion of each of the electrode pads 14 is exposed.

As shown in FIG. 2B, a photoresist layer 42 is applied to the passivation film 16. Thereafter, as shown in FIG. 2C, the photoresist layer 42 is exposed to light in accordance with the exposed portion of each of the electrode pads 14, so that openings 44 to expose respective electrode pads 14 are formed. Here, the width of each opening 44 is specified to be narrower than the opening width of the passivation film 16 and, in addition, each opening 44 is formed while being kept from contact with the end portion of the passivation film 16.

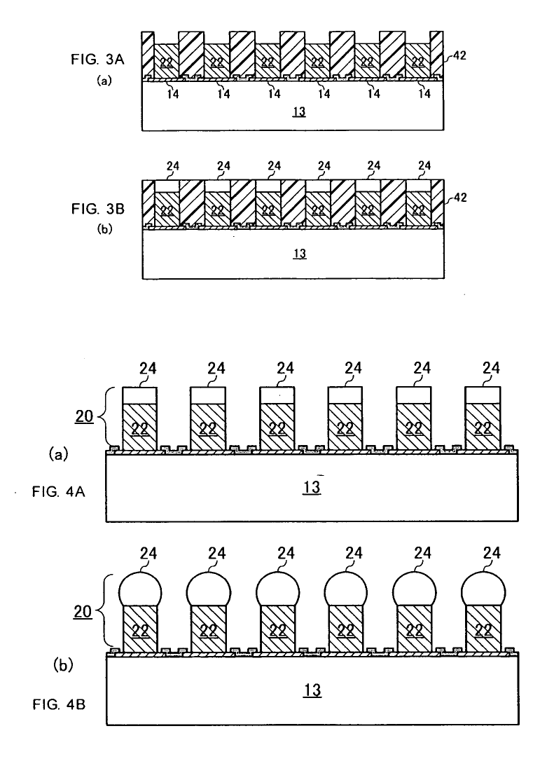

FIGS. 3A and 3B are sectional views showing a second production step of the semiconductor device according to the first embodiment. As shown in FIG. 3A, columnar portions 22 are formed on the electrode pads 14 by using the openings 44 shown in the above-described drawing. The columnar portions 22 are formed by copper plating.

As shown in FIG. 3B, low-melting point layers 24 are formed on the top surfaces of the columnar portions 22 by using the openings 44 shown in the above-described drawing. The low-melting point layers 24 are formed by solder plating.

FIGS. 4A and 4B are sectional views showing a third production step of the semiconductor device according to the first embodiment. As shown in FIG. 4A, the photoresist layer 42 shown in the above-described drawing is removed, so that a plurality of columnar electrodes 20 disposed on the wafer 13 are produced. Subsequently, as shown in FIG. 4B, the low-melting point layers 24 are heated to melt, and the low-melting point layers 24 are processed into the shape of a ball. This heat-melting treatment is conducted by putting the wafer 13 into a reflow furnace and heat-treating at a predetermined temperature for a predetermined time. An oxide film remover is applied before the reflow.

FIG. 5 is a sectional view showing a first mounting step of the semiconductor device according to the first embodiment. As shown in FIG. 5, when the semiconductor device 10 produced through a series of steps described above is mounted on the wiring substrate 30, the main surface side of the semiconductor device 10 is faced toward the wiring substrate 30, and the ball-shaped low-melting point layers 24 located at the front ends of the columnar electrodes 20 and a wiring pattern disposed on the wiring substrate 30 are aligned.

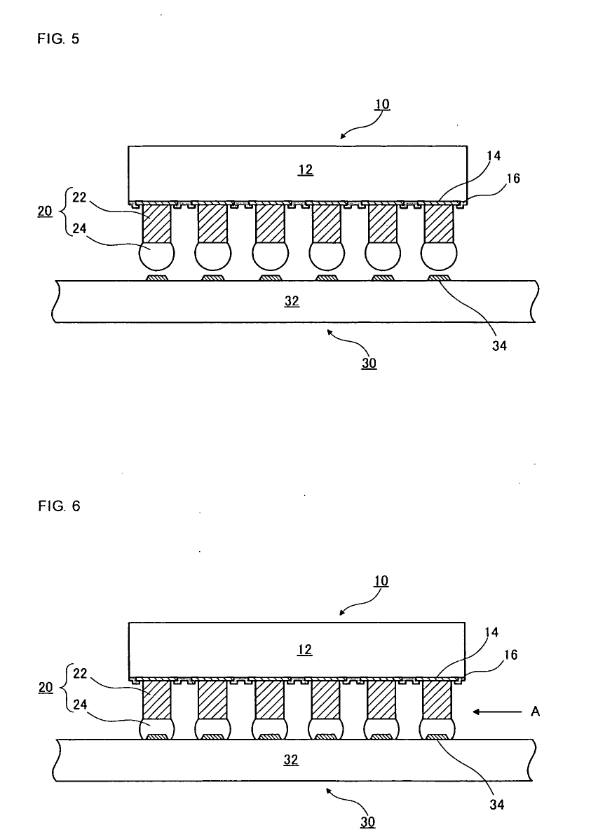

FIG. 6 is a sectional view showing a second mounting step of the semiconductor device according to the first embodiment. As shown in FIG. 6, the semiconductor device 10 aligned in the step shown in the above-described drawing is mounted on the wiring substrate 30. Thereafter, reflow is conducted, so that the low-melting point layers 24 are melted and fixed to the wiring pattern 34. After fixing of each low-melting point layer 24 is completed, an underfill resin is filled in from the direction indicated by an arrow A shown in FIG. 6 so as to produce the structure shown in FIG. 1.

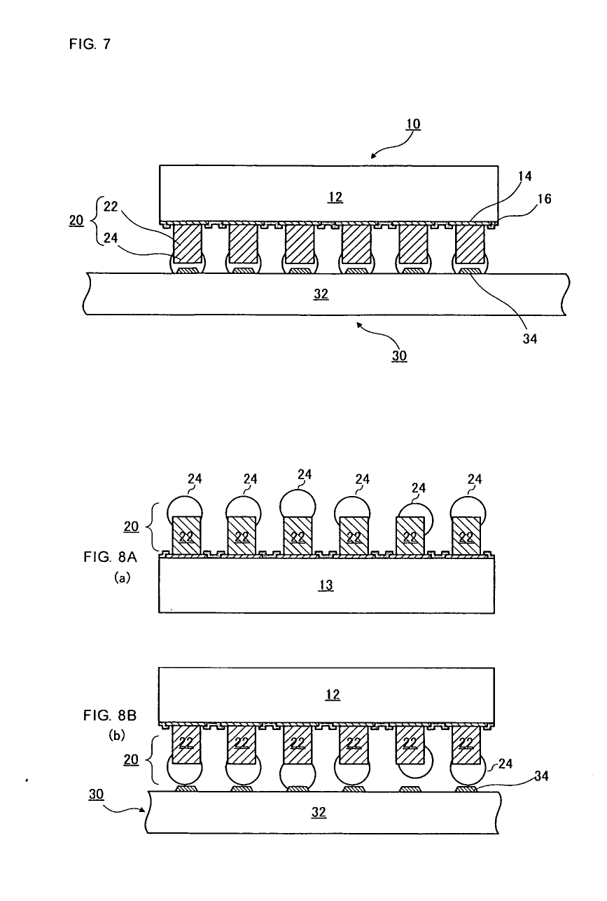

FIG. 7 is a sectional view showing another mounting structure of the semiconductor device according to the first embodiment. As shown in FIG. 7, the front end of the columnar portions 22 may be embedded in the low-melting point layers 24 when the semiconductor device 10 has been mounted on the wiring substrate 30.

FIGS. 8A and 8B are sectional views showing states of columnar electrodes exhibiting low connection reliability. As shown in FIG. 8A, if the ball-shaped low-melting point layers 24 are formed while being in contact with the side surfaces of the columnar portions 22, variations occur in the heights of individual columnar electrodes 20. Consequently, as shown in FIG. 8B, columnar electrodes not joined to the wiring pattern 34 result.

In order to prevent occurrence of this state in the present invention, a technique described below is applied to the step of forming the ball-shaped low-melting point layers 24 shown in FIG. 4B.

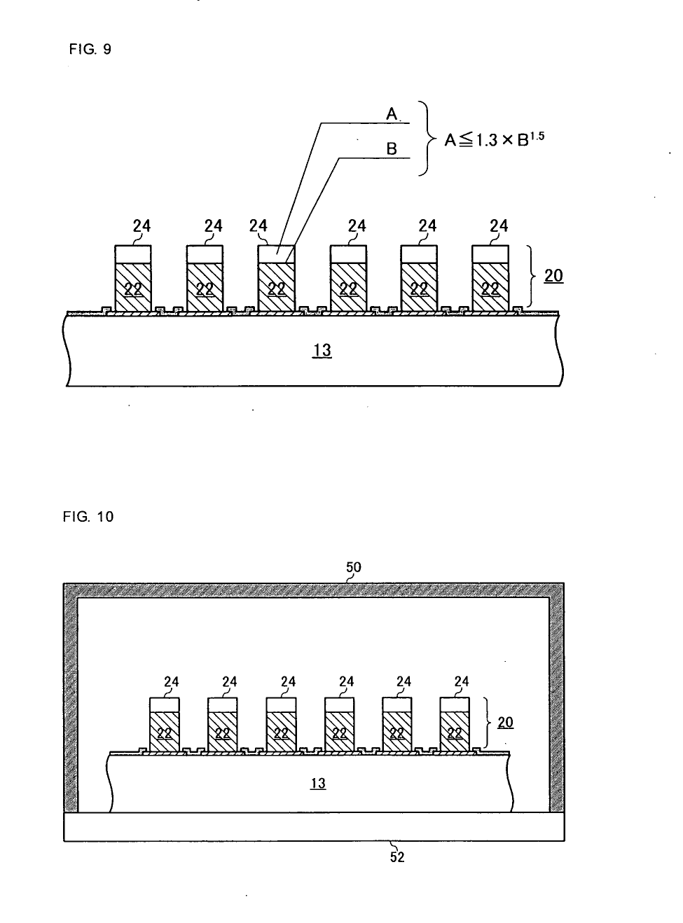

FIG. 9 is a sectional view showing the relationship between the volume of the low-melting point layer and the area of the top surface of the columnar portion shown in FIG. 4A. As shown in FIG. 9, the cross-sectional area of the opening 44 and the amount of plating of the low-melting point layer 24 are adjusted in such a way that the relationship represented by A≦1.3×B^{1.5} is satisfied, where the volume of each of the low-melting point layers 24 is represented by A and the area of the top surface of each of the columnar portions 22 is represented by B, in the above-described steps explained with reference to FIGS. 2A to 2C and FIGS. 3A and 3B, so that each columnar electrode 20 is formed.

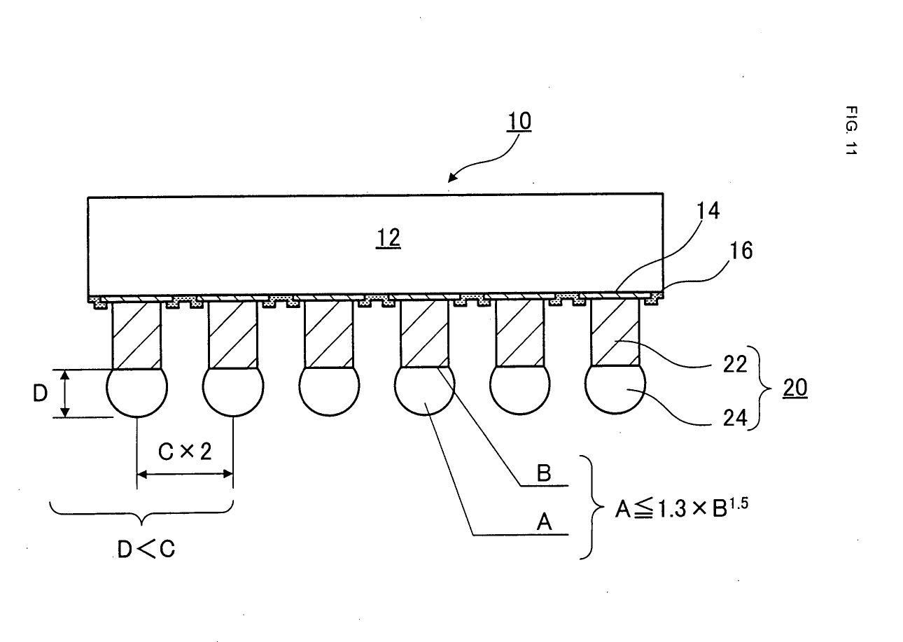

FIG. 10 is a side view showing a reflow step of a wafer provided with columnar electrodes. As shown in FIG. 10, after each columnar electrode 20 is formed satisfying the above-described relationship, the back of the wafer 13 provided with the individual columnar electrodes 20 is placed on a wafer support 52, and the wafer 13 is set with the low-melting point layers 24 up in a reflow furnace 50.

When the low-melting point layers 24 in this state are heated, the gravity is applied downward to the melted low-melting point layers 24. However, since the amount of the low-melting point layer 24 has been controlled in consideration of the area of the top surface of the columnar portion 22, the low-melting point layers 24 is processed into the shape of a ball while being kept from contact with the side surface of the columnar portion 22.

FIG. 11 is a sectional view showing an electrode structure of a semiconductor device formed by the step shown in FIG. 10. As shown in FIG. 11, each columnar electrode 20 of the semiconductor device 10 is formed through the step shown in FIG. 10 in such a way that the relationship represented by A≦1.3×B^{1.5} is satisfied, where the volume of each of the low-melting point layers 24 is represented by A and the area of the top surface of each of the columnar portions 22 is represented by B. In addition, each of the above-described columnar electrode satisfies the relationship represented by D<C, where one-half of the pitch between the individual columnar electrodes 20 is represented by C and the height of the ball-shaped low-melting point layer 24 is represented by D.

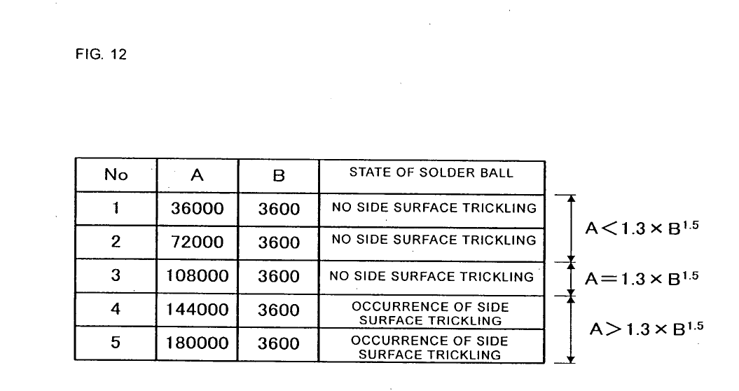

FIG. 12 is a table showing the results of verification of the relationship between the volume A of the low-melting point layer and the area B of the top surface of the columnar portion. As shown in FIG. 12, the values of A and B were changed and trickling of the low-melting point layer on the side surface of the columnar portion was evaluated. As a result, it was ascertained that the ball portion was able to be formed while no trickling on the side surface of the columnar portion occurred under the condition Nos. 1 to 3, whereas trickling on the side surface occurred under the condition Nos. 4 and 5.

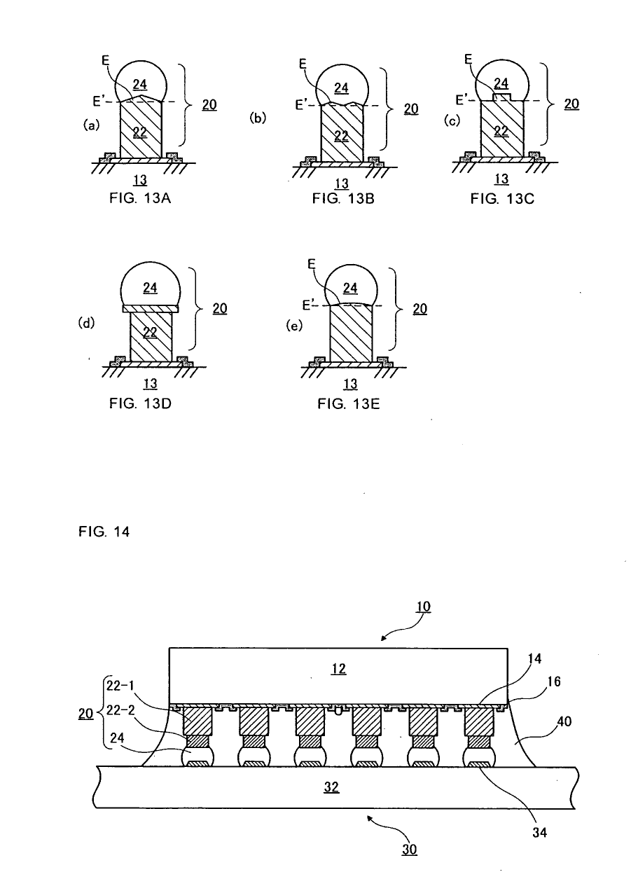

FIGS. 13A to 13E are sectional views showing examples of suitable structures of the columnar electrode. The above-described columnar electrode may have a structure in which the top surface of the columnar portion 22 is formed with portions that extend upward from a nominal flat upper surface and take the shape of a crest, as shown in FIG. 13A, may include a structure comprising one or more projections, as shown in FIGS. 13B and 13C, a structure including a convex portion at the center portion, as shown in FIG. 13C, a structure including a wide top surface, as shown in FIG. 13D, or a structure comprising a convexly curved upper surface, as shown in FIG. 13E.

In the case where the top surface takes a shape such as shown in FIGS. 13A, 13B, 13C, or 13E, the columnar electrode is formed satisfying the relationship represented by A−E≦1.3×B^{1.5}, where the volume of the portion located above the broken line E′ shown in FIGS. 13A, 13B, 13C, or 13E is represented by E. This broken line is a horizontal line which intersects the side surface of the columnar portion at a right angle and which is drawn at the top end of the solid columnar portion. The volume of the projecting portion protruding up from the horizontal line is represented by E. Such a projecting portion may be formed naturally in the plating step or be formed intentionally. The low-melting point material can be prevented from trickling on the side surface of the columnar portion by taking the volume of this projecting portion into consideration.

When these structures are adopted, the above-described area B of the top surface of the columnar portion 22 is defined as the total surface area of the columnar portion in contact with the low-melting point layer 24. Therefore, since a wide contact area between the low-melting point layer 24 and the columnar portion 22 is ensured by adopting these structures, the volume of the low-melting point layer can be increased.

FIG. 14 is a sectional view showing a mounting structure of a semiconductor device according to a second embodiment of the present invention. As shown in FIG. 14, a semiconductor device 10 is mounted on a wiring substrate 30 with columnar electrodes 20 therebetween in the present structure.

The semiconductor device 10 is composed of a semiconductor substrate 12 made of Si, GaAs, GaN, SiGe, or the like, a plurality of aluminum electrode pads 14 disposed on the main surface side of the semiconductor substrate 12, and a passivation film 16 disposed in such a way that each of the electrode pads 14 is partially exposed.

Each columnar electrode 20 is composed of columnar portions 22-1 and 22-2, each made of a high-melting point material, e.g., copper, nickel, or electrically conductive paste, and disposed on the exposed portion of each of the above-described electrode pads 14 and a low-melting point layer 24 made of solder or the like and disposed on the top surface of the columnar portion 22-2. It is desirable that the columnar portions together have a height of 15 μm or more.

Here, the columnar portions 22-1 and 22-2 are formed into shapes having mutually different diameters, and these are stacked to constitute one columnar portion. The columnar portion 22-2 has an outer diameter smaller than that of the columnar portion 22-1, and a low-melting point layer 24 is disposed on the surface having the small diameter. That is, the columnar portion is constructed from a plurality of stages, and has a configuration in which the diameter of the columnar portion is decreased stepwise or continuously in a direction from the semiconductor substrate 12 toward the low-melting point metal layer 24. Consequently, the low-melting point metal layer 24 is prevented from trickling on the side surface of the columnar portion in the formation of the ball-shaped low-melting point metal layer 24 by reflow or the like.

The wiring substrate 30 is composed of a multilayer substrate 32 including various pattern layers and a wiring pattern 34 disposed on a surface of the multilayer substrate 32.

Electrical connection between the semiconductor device 10 and the wiring substrate 30 is conducted by melting the low-melting point layers 24, which is located at front end portions of the columnar electrodes 20, on the wiring pattern 34, and an underfill 40 is applied in between the semiconductor device 10 and the wiring substrate 30, so that the joining state through each of the columnar electrodes 20 is protected.

FIGS. 15A to 15C are sectional views showing a first production step of the semiconductor device according to the second embodiment. In the production of the semiconductor device according to the present embodiment, as shown in FIG. 15A, a plurality of electrode pads 14 are formed on the main surface side of a wafer 13 provided with a plurality of integrated circuits, and a passivation film 16 is formed in such a way that a center portion of each of the electrode pads 14 is exposed.

As shown in FIG. 15B, a photoresist layer 42-1 is applied to the passivation film 16. Thereafter, as shown in FIG. 15C, the photoresist layer 42-1 is exposed to light in accordance with the exposed portion of each of the electrode pads 14, so that openings 44 to expose respective electrode pads 14 are formed. Here, it is desirable that the width of each opening 44 is specified to be narrower than the opening width of the passivation film 16 and, in addition, each opening 44 is formed while being kept from contact with the end portion of the passivation film 16. However, each opening 44 may be formed having a width wider than the opening width of the passivation film 16.

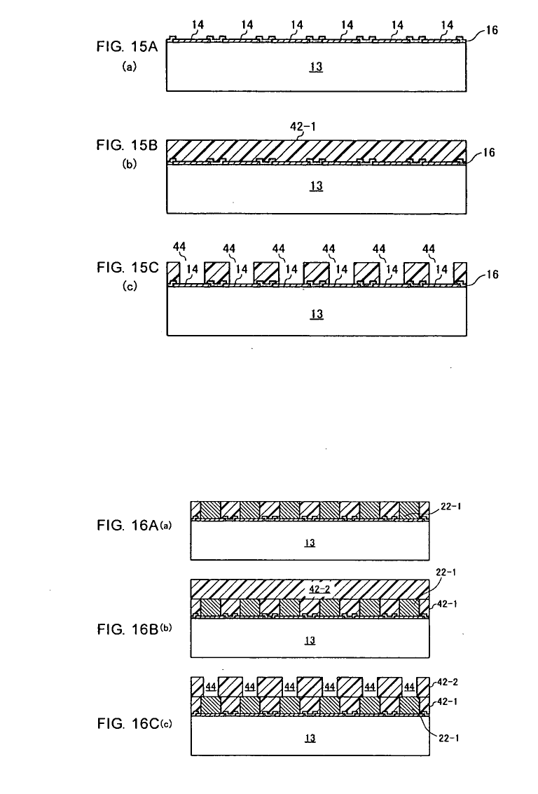

FIGS. 16A to 16C are sectional views showing a second production step of the semiconductor device according to the second embodiment. As shown in FIG. 16A, columnar portions 22-1 are formed on the electrode pads 14 by using the openings 44 shown in the above-described drawings. The columnar portions 22-1 are formed by copper plating, nickel plating, or a printing method to fill in an electrically conductive paste.

As shown in FIG. 16B, a photoresist layer 42-2 is applied to the photoresist layer 42-1. Thereafter, as shown in FIG. 16C, the photoresist layer 42-2 is exposed to light in accordance with the exposed portion of each of the columnar portions 22-1, so that openings 44 to expose respective columnar portions 22-1 are formed. Here, the width of each opening 44 is specified to be narrower than the width of each of the columnar portions 22-1.

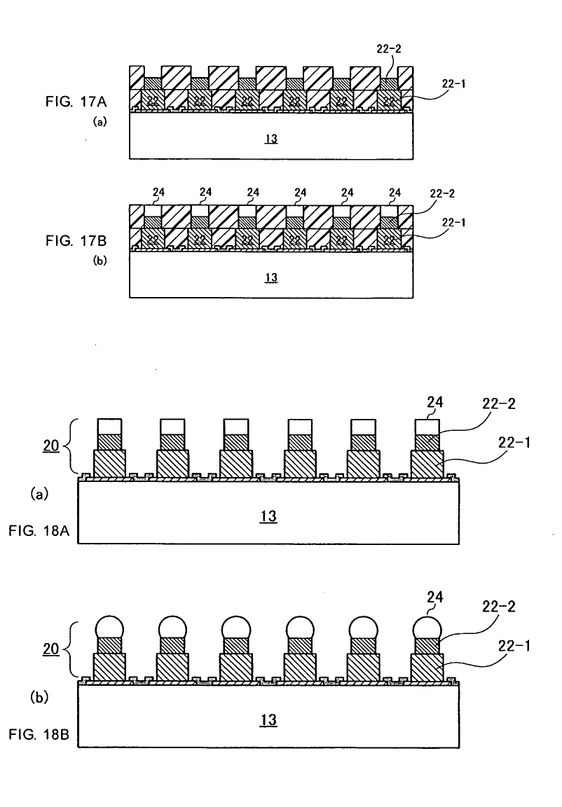

FIGS. 17A and 17B are sectional views showing a third production step of the semiconductor device according to the second embodiment. As shown in FIG. 17A, columnar portions 22-2 are formed on the columnar portions 22-1 by using the openings 44 shown in the above-described drawings. The columnar portions 22-2 are formed by copper plating, nickel plating, or a printing method to fill in an electrically conductive paste.

As shown in FIG. 17B, low-melting point layers 24 are formed on the top surfaces of the columnar portions 22-2 by using the openings 44 shown in FIG. 16C. The low-melting point layers 24 are formed by solder plating.

FIGS. 18A and 18B are sectional views showing a fourth production step of the semiconductor device according to the second embodiment. As shown in FIG. 18A, the photoresists 42-1 and 42-2 shown in the above-described drawings are removed, so that a plurality of columnar electrodes 20 disposed on the wafer 13 are produced. Subsequently, as shown in FIG. 18B, the low-melting point layers 24 are heated to melt, and the low-melting point layers 24 are processed into the shape of a ball. This heat-melting treatment is conducted by putting the wafer 13 into a reflow furnace and heat-treating at a predetermined temperature for a predetermined time. An oxide film remover is applied in advance of the reflow.

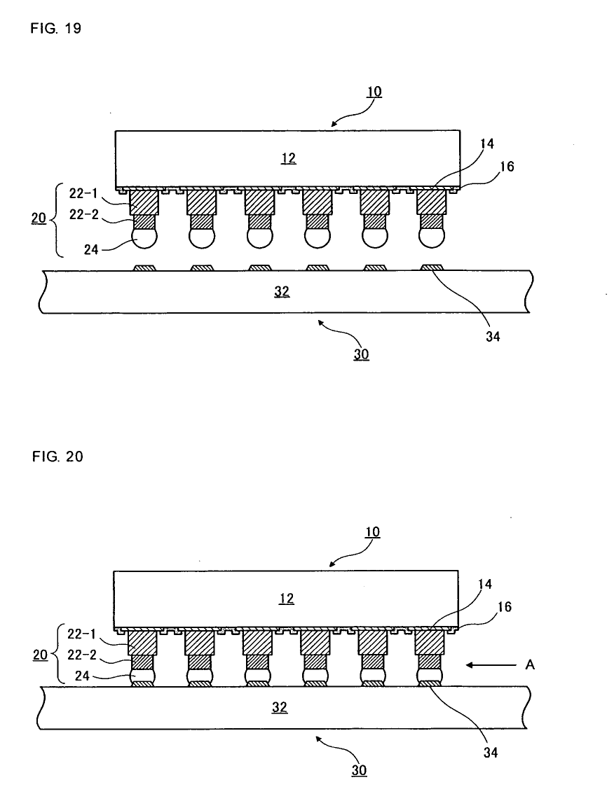

FIG. 19 is a sectional view showing a first mounting step of the semiconductor device according to the second embodiment. As shown in FIG. 19, when the semiconductor device 10 produced through a series of steps described above is mounted on the wiring substrate 30, the main surface side of the semiconductor device 10 is faced toward the wiring substrate 30, and the ball-shaped low-melting point layers 24 located at the front ends of the columnar electrodes 20-2 and a wiring pattern disposed on the wiring substrate 30 are aligned.

FIG. 20 is a sectional view showing a second mounting step of the semiconductor device according to the second embodiment. As shown in FIG. 20, the semiconductor device 10 aligned in the step shown in the above-described drawing is mounted on the wiring substrate 30. Thereafter, reflow is conducted, so that the low-melting point layers 24 are melted and fixed to the wiring pattern 34. After fixing of each low-melting point layer 24 is completed, an underfill resin is filled in from the direction indicated by an arrow A shown in FIG. 20 so as to produce the structure shown in FIG. 14.

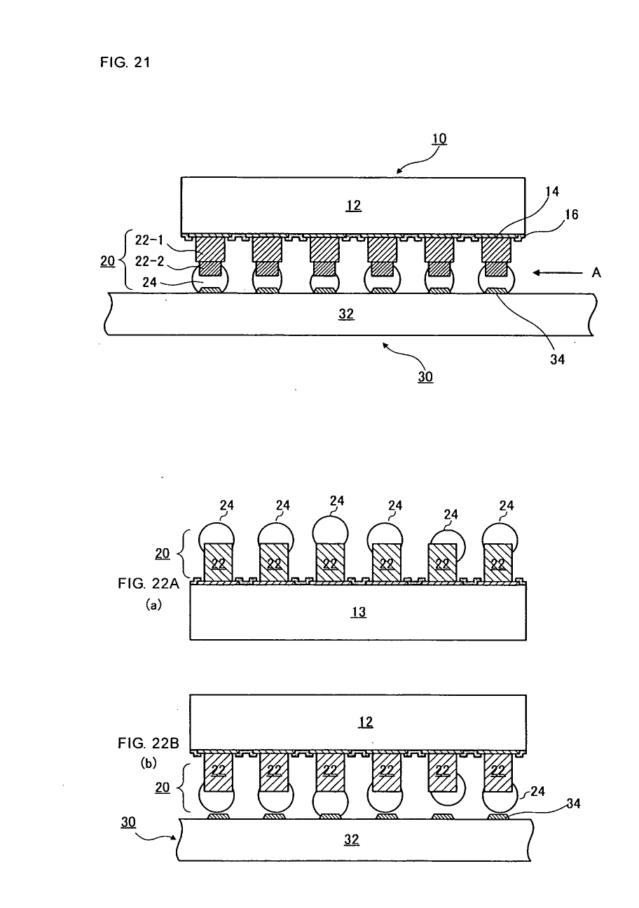

FIG. 21 is a sectional view showing another mounting structure of the semiconductor device according to the second embodiment. As shown in FIG. 21, the front ends of the columnar portions 22-2 may be embedded in the low-melting point layers 24 when the semiconductor device 10 has been mounted on the wiring substrate 30.

FIGS. 22A and 22B are sectional views showing states of columnar electrodes exhibiting low connection reliability. As shown in FIG. 22A, if the ball-shaped low-melting point layers 24 are formed while being in contact with the side surfaces of the columnar portions 22, variations occur in the heights of individual columnar electrodes 20. Consequently, as shown in FIG. 22B, columnar electrodes not joined to the wiring pattern 34 result.

In order to prevent occurrence of this state in the present invention, as shown in FIGS. 18A and 18B, sections having different diameters are disposed in the columnar portion. Consequently, in the step of forming a ball-shaped low-melting point layer 24, the low-melting point layer 24 is prevented from trickling and extending on at least the side surface of the columnar portion 22-1 when the low-melting point layer 24 is melted.

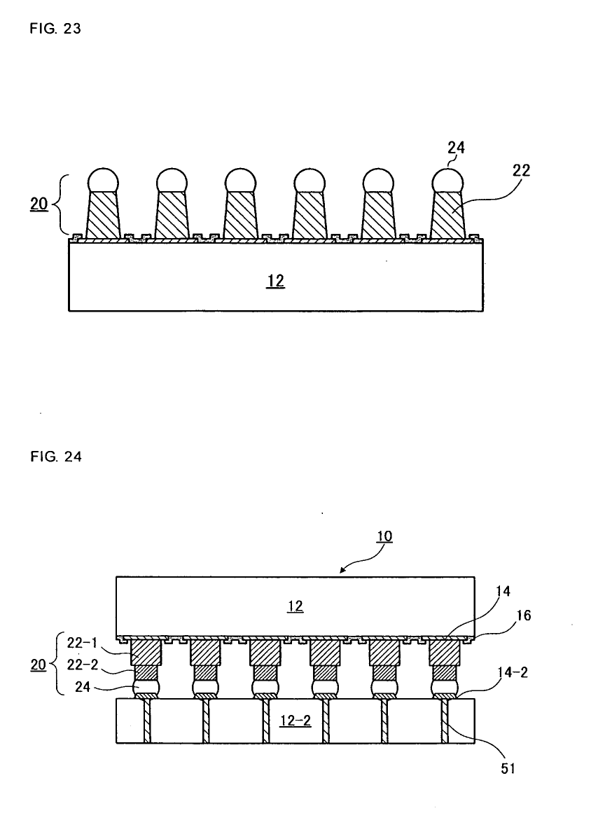

FIG. 23 is a sectional view showing an embodiment in the case where a trapezoidal columnar portions are used. As shown in FIG. 23, the columnar electrode 20 may be constructed by using the trapezoidal columnar portion 22 in which the diameter on the low-melting point layer 24 side is small and the diameter on the semiconductor substrate 12 side is large. The low-melting point layer 24 is prevented from trickling and extending on the side surface of the columnar portion 22 by such a structure when the low-melting point layer 24 is melted.

FIG. 24 is a sectional view showing an example of joining to via holes disposed in a semiconductor substrate. As shown in FIG. 24, an electrode pad 14-2 may be formed on a via hole 51 passing through the semiconductor substrate 12-2 and a low-melting point layer 24 may be joined to the electrode pad in the configuration. Here, the via hole 51 is formed by filling copper or an electrically conductive paste in a through hole formed in the semiconductor substrate 12-2.

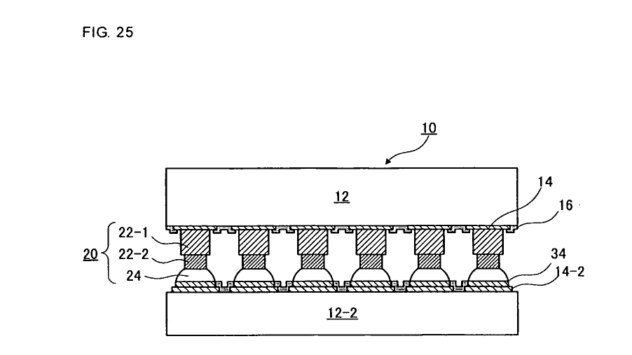

FIG. 25 is a sectional view showing an example of joining to an electrode pattern disposed on a semiconductor substrate. As shown in FIG. 25, a wiring pattern 34 may be formed on electrode pads 14-2 disposed on the main surface of the semiconductor substrate and low-melting point layers 24 may be joined to the wiring pattern 34 in the configuration.

According to the present invention, columnar electrodes including ball-shaped low-melting point layers joined to only the top surfaces of columnar portions can be formed. Therefore, it can be applied to a semiconductor device, where miniaturization and pitch reduction are required.

What is claimed is:

1. A semiconductor device comprising a plurality of columnar electrodes disposed on a semiconductor substrate, the columnar electrode comprising:
a columnar portion made of an electrically conductive material or materials; and
a metal ball portion made of an electrically conductive material or materials having a melting point lower than that of the columnar portion and joined to the top surface of the columnar portion,
wherein the columnar electrode satisfies the relationship represented by A−E≦1.3×B^{1.5}, where the volume of the metal ball portion is represented by A, the area of the top surface of the columnar portion in contact with the metal ball portion is represented by B, and the volume of an optional projecting portion disposed on the top surface of the columnar portion is represented by E, wherein E=0 if there is no projecting portion.

2. The semiconductor device according to claim 1, wherein each of the columnar electrodes satisfies the relationship represented by D<C, where one-half of the pitch between the individual columnar electrodes is represented by C and the height of the metal ball portion is represented by D.

3. An electronic apparatus equipped with a semiconductor device which comprises a plurality of columnar electrodes disposed on a semiconductor substrate and which is mounted on a wiring substrate with the individual columnar electrodes therebetween, the columnar electrode comprising:
a columnar portion made of an electrically conductive material or materials; and
a low-melting point metal layer made of an electrically conductive material or materials having a melting point lower than that of the columnar portion and joined to the top surface of the columnar portion,
wherein the columnar electrode satisfies the relationship represented by A−E≦1.3×B^{1.5}, where the volume of the low-melting point metal layer is represented by A, the area of the top surface of the columnar portion in contact with the metal ball portion is represented by B, and the volume of an optional projecting portion disposed on the top surface of the columnar portion is represented by E, wherein E=0 if there is no projecting portion.

4. The electronic apparatus according to claim 3, wherein an underfill filled in between the semiconductor device and the wiring substrate while being in direct contact with side surfaces of the columnar portions is provided.

5. The electronic apparatus according to claim 3, wherein each of the columnar electrodes satisfies the relationship represented by D<C, where one-half of the pitch between the individual columnar electrodes is represented by C and the height of the metal ball portion is represented by D.

6. A semiconductor device comprising a plurality of columnar electrodes disposed on a semiconductor substrate, the columnar electrode comprising:
first and second columnar portions made of an electrically conductive material or materials; and
a metal ball portion made of an electrically conductive material having a melting point lower than that of the columnar portion and joined to the top surface of the second columnar portion,
wherein the second columnar portion includes a section having a diameter smaller than the diameter of the first columnar portion and is interposed between the metal ball portion and the first columnar portion.

7. A semiconductor device comprising a plurality of columnar electrodes disposed on a semiconductor substrate, the columnar electrode comprising:
a columnar portion made of an electrically conductive material or materials; and
a metal ball portion made of an electrically conductive material or materials having a melting point lower than that of the columnar portion and joined to the top surface of the columnar portion,
wherein the columnar portion has a smaller cross sectional area at the end affixed to the substrate than at the end affixed to the metal ball.
